(19) United States
(12) Patent Application Publication
(10) Pub. No.: US 2026/0031608 A1
(43) Pub. Date: Jan. 29, 2026

(54) FAULT DETECTOR WITH INTELLIGENT POWER RESTORE

(71) Applicant: Southwire Company, LLC, Carrollton, GA (US)

(72) Inventor: Donald Paul Oldham, JR., Trinity, FL (US)

(21) Appl. No.: 19/282,635

(22) Filed: Jul. 28, 2025

Related U.S. Application Data
(60) Provisional application No. 63/676,793, filed on Jul. 29, 2024.

(51) Int. Cl. H02H 7/22; G01R 19/25

(52) U.S. Cl. CPC H02H 7/22; G01R 19/2513

(57) ABSTRACT

An apparatus for detecting fault conditions in a power system is described. The apparatus may include one or more powered lines configured to output electricity to an electrical distribution system, a neutral line, an interrupter, and a controller. The controller may be configured for detecting when a fault condition is present in the power system. In response to detecting that the fault condition is present, the controller may cause the interrupter to interrupt the power supplied by the one or more powered lines. In response to detecting that the fault condition is no longer present, the controller may determine a power restoration delay time and cause the one or more powered lines to supply power to the electrical distribution system when the power restoration delay time has been elapsed.

### CROSS-REFERENCE TO RELATED APPLICATIONS

This application claims priority to U.S. Provisional Patent Application No. 63/676,793, filed on Jul. 29, 2024, which is incorporated herein by reference in its entirety.

### BACKGROUND

Recreational vehicles (RVs) are generally designed with the capability to connect to an external power source to supply electrical power to the RV. Poor power quality entering an RV can not only affect the longevity of the electronic equipment and motors but can cost thousands of dollars in repairs and create frustrating unnecessary travel delays.

Many RV power services are located in campgrounds (e.g., RV parks) or other outdoor environments. While the quality of power entering a home is generally consistent, the same cannot be said for campgrounds or other outdoor environments. Power quality in campgrounds is subject to vast fluctuations and is dependent upon many factors. Intensity of electrical loads placed on the campground, weather conditions, faulty wiring, and undersized or deteriorating electrical connections can affect the quality of power entering an RV. With today's RV containing sophisticated and sensitive electronics, a few short seconds of faulty power can damage equipment within the coach, such as inverters, converters, microwaves, televisions, and refrigerators. Examples of faulty power include, but are not limited to, high voltage, low voltage, mis-wired power pedestals, open neutral, open ground, reverse polarity, high neutral current surges, and overheating plug/receptacle.

To protect their electronics and RV electrical systems, RV owners connect their RVs to power pedestals at campgrounds via surge protectors. These surge protectors may be designed to remove power to the RV when faulty power is detected and return power to the RV when the power is stable. However, returning power too quickly to the RV after faulty power is detected can trip the breaker or cause damage. For example, air conditioning units (e.g., air conditioners) can retain pressure that can cause a circuit breaker to trip if power is reapplied immediately after a power interruption. On the other hand, waiting too long to return power to the RV can cause unnecessary and frustrating delays with respect to the use of the electronics/electrical appliances in the coach. Current practiced state of the art of reapplication of power is either adding a permanent long delay each time power is detected, which may not be required during initially plugging in, which frustrates customers, or adding a permanent short delay, which will miss a necessary long delay due to a brief brown out.

Accordingly, there is an ongoing need in the art to provide a fault detector with intelligent power restoration.

### BRIEF SUMMARY

According to one aspect of the of the present disclosure an apparatus for detecting fault conditions in a power system for delivering power to an electrical distribution system is provided. In various embodiments, the apparatus includes one or more powered lines configured to output electricity to the electrical distribution system; a neutral line configured to provide a grounded neutral to the one or more powered lines; an interrupter configured to selectively interrupt power supplied by the one or more powered lines; and a controller in communication with the interrupter, the controller configured for: detecting when a fault condition is present in the power system; in response to detecting that the fault condition is present, causing the interrupter to interrupt the power supplied by the one or more powered lines; and in response to detecting that the fault condition is no longer present: (i) determining a power restoration delay time, and (ii) causing the one or more powered lines to supply power to the electrical distribution system when the power restoration delay time has been elapsed.

In some example embodiments, the apparatus further comprises a resistive-capacitive circuit, wherein the controller is in communication with the resistive-capacitive circuit, and wherein the controller is further configured to cause a capacitor of the resistive-capacitive circuit to begin discharging in response to detecting that the fault condition is present.

In some example embodiments, the controller is further configured to cause current to flow to the capacitor to recharge the capacitor when the power restoration delay time has been elapsed.

In some example embodiments, the controller is further configured to determine a capacitor voltage of the capacitor in response to detecting that the fault condition is no longer present; and determine the power restoration delay time based on the capacitor voltage.

In some example embodiments, the power restoration delay time is less than ten seconds when the capacitor voltage is not greater than a minimum threshold voltage.

In some example embodiments, the controller is configured to determine the power restoration delay time when the capacitor voltage is greater than a threshold voltage by determining a discharge time for the capacitor to discharge to the capacitor voltage; and determining a difference between a threshold delay time and the discharge time, wherein the power restoration delay time is the difference between the threshold delay time and the discharge time.

In some example embodiments, the controller comprises a microprocessor, wherein the microprocessor is configured for measuring the capacitor voltage.

In some example embodiments, the controller comprises an analog comparator circuit configured for measuring the capacitor voltage.

In some example embodiments, the controller comprises an analog to digital converter configured for measuring the capacitor voltage.

In some example embodiments, the controller is configured to detect that the fault condition is no longer present when power from a power source configured to supply power to the one or more powered lines satisfies one or more power condition criteria.

In some example embodiments, the interrupter comprises a driver interface in communication with the controller; and a contactor connected to the driver interface and configured to interrupt the power from the power source when the fault condition is detected.

In some example embodiments, the fault condition comprises one or more of an open neutral condition, a high voltage condition, a low voltage condition, a mis-wired power pedestal condition, an open ground condition, a reverse polarity condition, a high neutral current surge condition, an overheating plug condition, or a loss of power source condition.

According to another aspect of the of the present disclosure, an apparatus for detecting fault conditions in a power system for delivering power to an electrical distribution system is provided. In various embodiments, the apparatus may include one or more powered lines configured to output electricity to the electrical distribution system; a neutral line configured to provide a grounded neutral to the one or more powered lines; an interrupter configured to selectively interrupt power supplied by the one or more powered lines; a timer circuit comprising a counter; and a controller in communication with the interrupter and the timer circuit, the controller configured for: detecting when a fault condition is present in the power system; in response to detecting that the fault condition is present, causing the interrupter to interrupt the power supplied by the one or more powered lines and activating the counter; and in response to detecting that the fault condition is no longer present: (i) determining a remaining count via the counter; (ii) determining a power restoration delay time based on the remaining count and, (iii) causing the one or more powered lines to supply power to the electrical distribution system when the power restoration delay time has been elapsed.

In some example embodiments, activating the counter comprises causing the counter to count down, and wherein the power restoration delay time is less than ten seconds when the remaining count is not greater than a minimum remaining count.

In some example embodiments, the controller is configured to determine the power restoration delay time when the remaining count is greater than the minimum remaining count by determining a difference between a threshold delay time and the remaining count, wherein the power restoration delay time is the difference between the threshold delay time and the remaining count.

In some example embodiments, the controller is configured to detect that the fault condition is no longer present when power from a power source configured to supply power to the one or more powered lines satisfies one or more power condition criteria.

According to another aspect of the of the present disclosure, an apparatus for detecting fault conditions in a power system for delivering power to an electrical distribution system is provided. In various embodiments, the apparatus may include one or more powered lines configured to output electricity to the electrical distribution system; a neutral line configured to provide a grounded neutral to the one or more powered lines; an interrupter configured to selectively interrupt power supplied by the one or more powered lines; a clock; and a controller in communication with the interrupter and the clock, the controller configured for: detecting when a fault condition is present in the power system; in response to detecting that the fault condition is present, causing the interrupter to interrupt the power supplied by the one or more powered lines and determining, via the clock, a first timestamp; and in response to detecting that the fault condition is no longer present: (i) determining, via the clock, a second timestamp; (ii) determining a power restoration delay time based on the first timestamp and the second timestamp, and (iii) causing the one or more powered lines to supply power to the electrical distribution system when the power restoration delay time has been elapsed.

In some example embodiments, the controller is configured to determine the power restoration delay time by determining a difference between the second timestamp and the first timestamp and comparing the difference between the second timestamp and the first timestamp to a threshold delay time.

In some example embodiments, the power restoration delay time is less than ten seconds when the difference between the second timestamp and the first timestamp is greater than the threshold delay time.

In some example embodiments, the power restoration delay time is the difference between the second timestamp and the first timestamp when the difference between the second timestamp and the first timestamp is less than the threshold delay time.

### BRIEF DESCRIPTION OF THE DRAWINGS

Reference will now be made to the drawings, which are not necessarily drawn to scale, and wherein:

FIG. 1 shows a schematic diagram of a fault detector system in accordance with at least one embodiment of the present disclosure.

FIGS. 2A and 2B each show an example process flow for determining a power restoration delay time for restoring power to an electrical distribution system in accordance with at least some embodiments of the present disclosure.

FIGS. 3A-3D each show an example process flow for determining a power restoration delay time for restoring power to an electrical distribution system in accordance with at least some embodiments of the present disclosure.

FIG. 4 shows an example process flow for determining a power restoration delay time for restoring power to an electrical distribution system in accordance with at least some embodiments of the present disclosure.

FIGS. 5A-C each show a schematic diagram of an apparatus for detecting fault conditions and restoring power to an electrical distribution system in accordance with at least some embodiments of the present disclosure.

FIG. 6 shows an exemplary block diagram of a fault detector controller in accordance with at least some embodiments of the present disclosure.

FIG. 7 shows an example application embodiment of a surge protector, in accordance with at least some embodiments of the present disclosure.

FIGS. 8A-8D each show a schematic diagram of a smart delay device in accordance with at least one embodiment of the present disclosure.

FIG. 9 shows a schematic diagram of an example controller with integrated smart delay functionality in accordance with at least one embodiment of the present disclosure.

FIG. 10 shows an example application embodiment of a smart delay device in accordance with at least one embodiment of the present disclosure.

### DETAILED DESCRIPTION OF VARIOUS EMBODIMENTS

Various embodiments of the present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. Like numbers refer to like elements throughout.

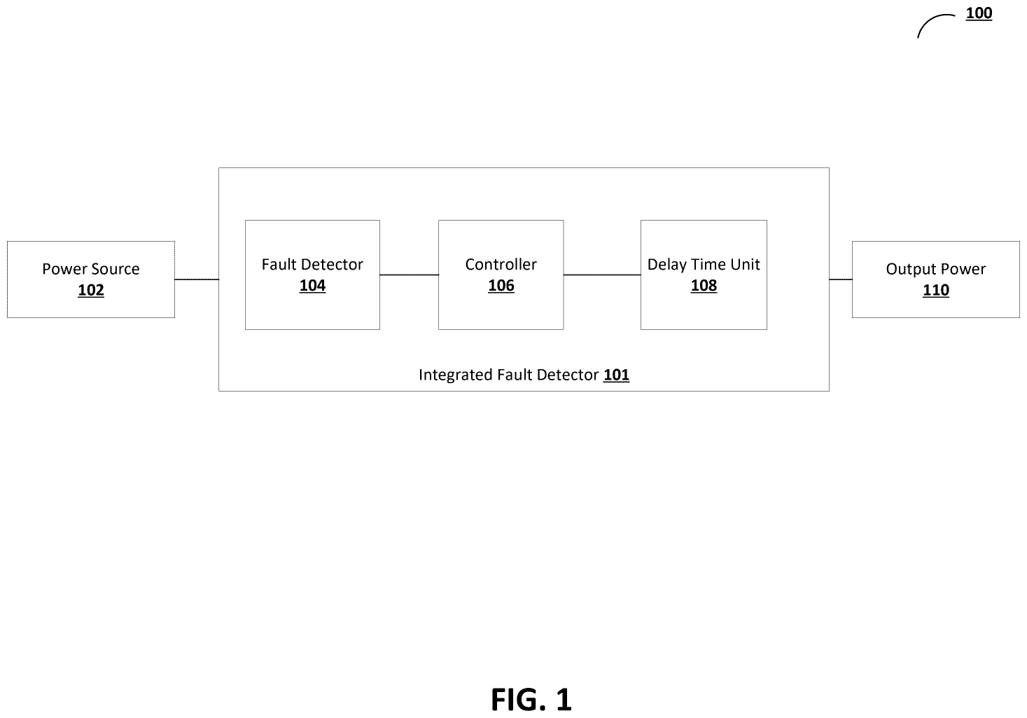

Various embodiments of the present invention are directed to a fault detector system 100. FIG. 1 shows a schematic diagram of a fault detector system 100 in accordance to at least some embodiments of the present disclosure. The fault detector system 100 may be configured for detecting one or more fault conditions in a power system for delivering power to an electrical distribution system such as, but not limited to, the electrical distribution system of an RV. Examples of such fault conditions include high voltage condition, low voltage condition, mis-wired power pedestal condition, open neutral condition, open ground condition, reverse polarity condition, missing powered line condition, overheating plug condition, or power source loss. According to various embodiments, the fault detector system 100 is configured to selectively interrupt power supplied to the electrical distribution system when certain fault conditions are detected. According to various embodiments, the fault detector system 100 is configured to determine an optimal power restoration delay time for restoring power to the electrical distribution system when fault condition(s) in the powered system are no longer present and restore power to the electrical distribution system after the power restoration delay time has been elapsed. Alternatively or additionally, according to various embodiments, the fault detector system 100 is configured to detect the occurrence of loss of power source (e.g., loss of power supplied from the RV power pedestal or other power sources) and determine an optimal power restoration delay time for restoring power to the electrical distribution system when the loss of power source is no longer present (e.g., when power returns). According to various embodiments, the power restoration delay time is the amount of time the fault detector system 100 waits before restoring power to the electrical distribution system after power is applied following loss of the power source, after fault(s) conditions are no longer present in the power system, or otherwise after power is applied following interruption of the power supply to the electrical distribution system whether due to loss of power source or due to a fault condition. According to various embodiments, the power restoration delay time is at least a threshold delay time. The threshold delay time may be the minimum amount of time to wait after power supply to an electrical distribution system is interrupted (e.g., due to loss of power source and/or due to a fault condition) to prevent damage to the electrical distribution system and/or appliances supplied by the electrical distribution system.

In some embodiments, the threshold delay time is two minutes. In some embodiments, the threshold delay time is five minutes. It will be understood that the threshold delay time may be greater than five minutes, less than two minutes, or between two and five minutes in other examples.

In the illustrated embodiment of FIG. 1, the fault detector system 100 includes a power source 102, an integrated fault detector 101, and an output power 110. As shown in FIG. 1, the integrated fault detector 101 includes a fault detector 104, a controller 106, and a delay time unit 108, The depiction of the fault detector system 100 is not intended to limit or otherwise confine the embodiments described and contemplated herein to any particular configuration nor is it intended to exclude any alternative configuration that can be used in connection with embodiments of the present disclosure. It will be understood that while many of the aspects and components presented in FIG. 1 are shown as discrete, separate elements, other configurations may be used in connection with the methods, apparatuses, and systems described herein, including configurations that combine, omit, separate, and/or add aspects and/or components. For example, in some embodiments, two or more of the controller 106, fault detector 104, or delay time unit 108 may be combined in the same unit. In some embodiments and as further described below, the delay time unit 108 and/or controller 106 may be external to the integrated fault detector 101. For example, the delay time unit 108 may be configured as a stand-alone device that can be coupled to, integrated within, or otherwise utilized in any of a variety of devices, equipment, and/or systems (e.g., fault detector systems, fault detectors, surge protectors, equipment (e.g., refrigerators, air conditioning units, and/or the like), transfer switches, or the like). In some embodiments, the stand-alone device may include a controller such as controller 106 or other type of controller.

According to various embodiments, the power source 102 comprises one or more powered lines and one neutral line configured to, for example, provide a grounded neutral for the one or more powered lines. In some embodiments, the power source 102 is configured to provide split-phase power. In such embodiments, the power source 102 may comprise two powered lines and one shared neutral line. Further, in such embodiments, the power source 102 may be a 50 A RV service provided at a power pedestal. In some embodiments, the power source 102 is configured to provide a single-phase power. In such embodiments, the power source 102 may comprise one powered line and one neutral line. Further, in such embodiments, the power source 102 may be a 30 A RV service provided at a power pedestal. The output power 110 may be configured to provide power to a RV, such as by a plug connection. In some embodiments, the power source 102 is configured to provide three-phase power. In such embodiments, the power source 102 may comprise three powered lines and a shared neutral line. In some embodiments, the fault detector 104 may be configured to monitor current on the neutral line and/or monitor current on at least one powered line to detect certain fault conditions such as, but not limited to, open neutral condition. For example, for a split-phase power system, the fault detector 104 may be configured to monitor the current on at least one of the two powered lines and/or monitor the current on the neutral line to detect an open neutral condition or other fault conditions. In such example, the fault detector 104 may be configured to detect an open neutral condition in the split-phase power system when at least one of the powered lines has current present and the neutral line has a zero or very low current. An example of methods of detecting an open neutral condition is provided in U.S. Pat. No. 10,868,417 titled Open Neutral Detector filed Dec. 8, 2017, the entire contents of which are incorporated herein by reference.

In some embodiments, the fault detector 104 may be configured to monitor the current on the neutral line and/or monitor the current on a powered line by means of software or firmware running on a processor or controller, such as controller 106. In some embodiments, the fault detector 104 may be configured to monitor the current on the neural line and/or monitor the current on a powered line using analog hardware. In some embodiments, monitoring current on the neural line comprises measuring the current on the neutral line. In some embodiments, monitoring current on a powered line comprises measuring the current on the powered line.

In some embodiments, the controller 106 is configured to perform the steps of detecting certain fault conditions. In some embodiments, the controller 106 may be configured to detect certain fault conditions based on monitored current on the neutral line and/or monitored current on a powered line. Such certain fault conditions may include open neutral, high voltage, low voltage, and/or other fault conditions.

Additionally, in some embodiments, the controller 106 may be configured to perform the steps of interrupting the power supplied to the electrical distribution system when certain fault conditions are detected. In some embodiments, the controller 106 interrupts the power supplied to the electrical distribution system by interrupting the power supply to the one or more powered lines (e.g., interrupting the power from the power source 102 to the one or more powered lines). In some embodiments, the controller 106 is configured to interrupt the power supplied to the electrical distribution system using a driver driving a switching device, such as a main contactor in the fault detector 104 to interrupt the power supply. Additionally, in some embodiments, the controller 106 is configured to detect when a loss of power source has occurred (e.g., loss of power supply from the RV power pedestal or other power source). In this regard, in some embodiments, the controller 106 is configured detect when power supplied to the electrical distribution system has been interrupted due to loss of power source.

Alternatively or additionally, in some embodiments, the controller 106 may be configured to perform the steps of determining the power restoration delay time for restoring power to the electrical distribution system when power supplied to the electrical distribution system is interrupted after a fault condition is detected and/or after power is applied following loss of power source, and restoring power to the electrical distribution system based on the power restoration delay time. In some embodiments, the controller 106 determines the power restoration delay time using the delay time unit 108.

In some embodiments, the delay time unit 108 includes a resistive-capacitive circuit comprising a voltage source, and a capacitor and resistor connected in parallel. In such embodiments, the controller 106 may be configured to cause the capacitor to discharge at least some of the voltage stored in the capacitor when power supplied to the electrical distribution system is interrupted and determine the power restoration delay time based on the remaining capacitor voltage on the capacitor when the fault condition is no longer present, power source loss is no longer present or otherwise when current is applied to the one or more powered lines after interruption of power whether due to loss of power source or due to a fault condition. The voltage source may be a battery or other voltage source separate from the power source 102. In some embodiments, the voltage source may be the power source 102. In some embodiments, the controller 106 is configured to cause the capacitor to begin discharging the voltage stored in the capacitor by causing a switching device component of the resistive-capacitive circuit to switch to an OFF state when power is interrupted such that the voltage source is disconnected from the capacitor. For example, the switching device may be configured to default to an OFF state when power is interrupted and default to an ON state when power is applied to the one or more powered lines to cause the capacitor to recharge. The controller 106 may be configured to cause the capacitor to recharge after the power restoration delay time has been elapsed and the power supply is stable (e.g., no faults), wherein the power restoration delay time is elapsed subsequent to power restoration after power interruption. In some embodiments, the switching device is a bilateral switch. In some embodiments, a capacitor voltage below a predetermined minimum voltage indicates that a threshold delay time for restoring power to the electrical distribution system has been elapsed. The threshold delay time may be the minimum amount of time for the fault detector system 100 to wait before restoring power to the electrical distribution system after power is applied following loss of the power source, after fault condition(s) are no longer present in the power system or otherwise after power is applied to the one or more powered lines after power interruption of the power supplied to the electrical distribution system (whether due to loss of power source or due to a fault condition) to prevent damage to the electrical distribution system and/or appliances supplied by the electrical distribution system. In some embodiments, the presence of voltage on the capacitor indicates that the minimum delay time (e.g., threshold delay time) for restoring power to the electrical distribution system has not been elapsed, thus, additional delay time may be needed to prevent damage to the electrical distribution system and/or appliances supplied by the electrical distribution system. In some embodiments, the controller may be configured to continuously or intermittently monitor the capacitor voltage, and when it reaches predetermined voltage, this indicates that the threshold delay time for restoring power to the electrical distribution system has been elapsed.

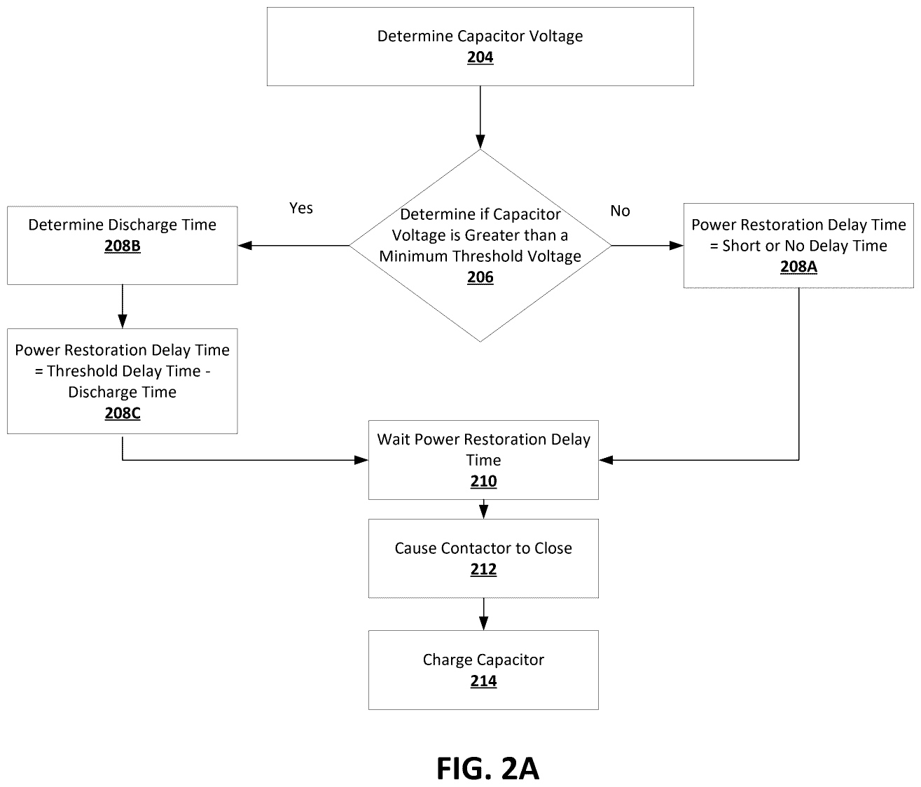

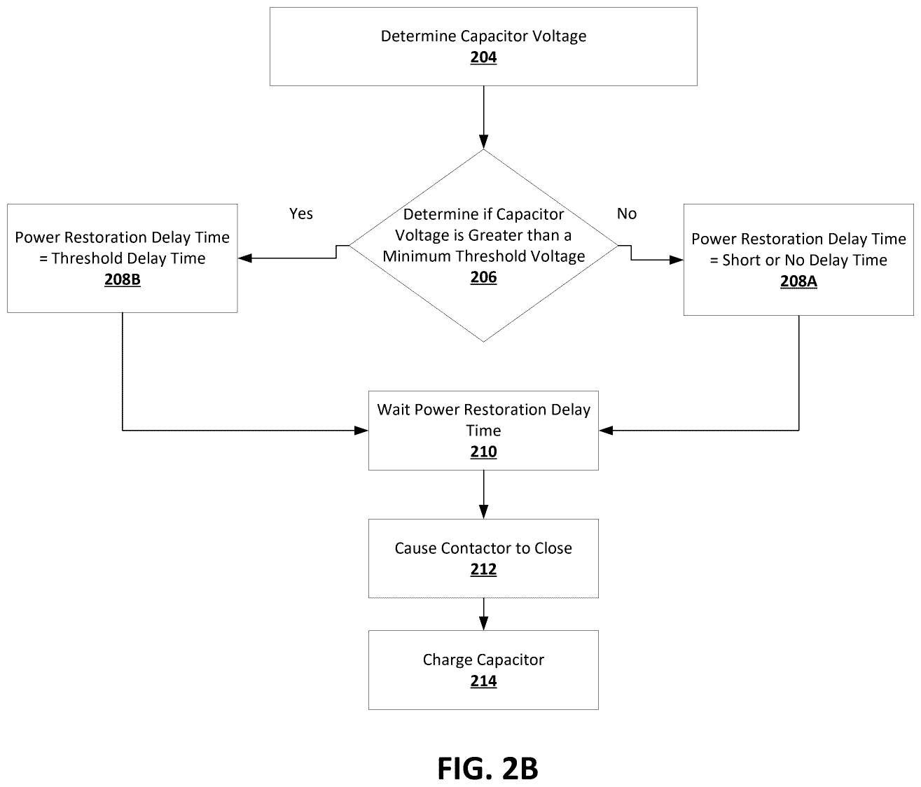

FIGS. 2A and 2B each show an example process flow for determining power restoration delay time for restoring power to an electrical distribution system using a resistive-capacitive circuit in accordance with at least some embodiments of the present disclosure. In some examples, the operations are performed utilizing a controller, such as controller 106. As described above, the power source 102 includes one or more powered lines configured to deliver power to an electrical distribution system. Further, as described above, the controller 106 may be configured to interrupt the power supplied to the electrical distribution system when a fault condition is detected by interrupting the power supply to the one or more powered lines. Further, as described above, the controller 106 may be configured to determine when a loss of power source has occurred, in which case, power supplied to the electrical distribution system is interrupted due to loss of power source.

Now referring to FIG. 2A, in some embodiments, at step/operation 204, when the fault condition is no longer present (e.g., steady-state condition), loss of power source is no longer present, or otherwise power is applied to the one or more powered lines after power interruption (e.g., in response to detecting fault condition(s) in the power system or power loss from the power source 102), the capacitor voltage (e.g., remaining voltage on the capacitor) is determined and utilized to determine the power restoration delay time. According to various embodiments, the fault condition may be determined to be no longer present when the power from the power source 102 satisfies one or more power condition criteria and/or when the power source is determined to be in a satisfactory operational condition. In some examples, the fault condition and/or loss of power source may be determined to be no longer present when power is applied to the one or more powered lines after a power source interruption. In some embodiments, determining the capacitor voltage may comprise measuring the capacitor voltage. In some embodiments, the capacitor voltage is measured using a processor or a microprocessor. For example, the controller may include a processor or a microprocessor configured for measuring or otherwise determining the capacitor voltage. In some embodiments, when power to the processor or microprocessor is removed, for example, due to loss of power source, the switching device (e.g., bilateral switch or the like) component of the resistive-capacitive circuit defaults to an OFF state and the capacitor discharges slowly through the resistor. In some embodiments, the capacitor voltage is measured using analog hardware. For example, the controller may include or otherwise utilize an analog comparator circuit for measuring the capacitor voltage. As another example, the controller may include or otherwise utilize an analog to digital converter (ADC) for measuring the capacitor voltage.

In some embodiments, at step/operation 206, the controller 106 determines if the capacitor voltage is greater than a minimum threshold voltage (e.g., above about zero volts or the like). The controller 106 may determine if the capacitor voltage is greater than the minimum threshold voltage by comparing the capacitor voltage to the minimum threshold voltage. In some embodiments, at step/operation 208A, if the controller 106 determines that the capacitor voltage is not greater than the minimum threshold voltage, the power restoration delay time is determined to be a predetermined delay time such as ten seconds, seven seconds, five seconds, or the like. In some example embodiments, the predetermined delay time is zero. It will be appreciated that the above examples of predetermined delay time are not intended to be limiting, and the predetermined delay time may be greater or less than the above examples. In some embodiments, the predetermined delay time is configurable. In some embodiments, at step/operation 208B, if the controller determines that the capacitor voltage is greater than the minimum threshold voltage, the discharge time for the capacitor to discharge to the capacitor voltage (e.g., the voltage on the capacitor when fault conditions are no longer present in the power system or otherwise when power is applied to the one or more powered lines following power interruption due to loss of power source or due to a fault condition) is determined. In some embodiments, at step/operation 208C, the difference between the threshold delay time and the discharge time is calculated to determine the power restoration delay time.

In some embodiments, the threshold delay time may correspond to the amount of time it takes the capacitor to fully charge or fully discharge. In some embodiments, at step/operation 210, the controller 106 waits the determined power restoration delay time before causing power to be restored to the electrical distribution system. In some embodiments, at step/operation 212, the controller 106 causes power to be restored to the electrical distribution system by driving a driver interface to drive a main contactor from an opened state to a closed state such that power supply to the electrical distribution system is no longer interrupted. At step/operation 214, the controller 106 may cause current to flow to the capacitor to recharge the capacitor. For example, the switching device coupled to the capacitor may be caused to switch from an OFF state to an ON. For example, the switching device may be caused to switch to the ON state in response to power being applied to the processor or microprocessor coupled to the switching device. In this regard, the controller 106 may cause the capacitor to recharge after the power restoration delay time has been elapsed and the power supply is stable (e.g., no faults).

Now referring to FIG. 2B, an alternative embodiment is described. In some embodiments, at step/operation 204, when the fault condition is no longer present, loss of power source is no longer present, or otherwise power is applied to the one or more powered lines after power interruption (e.g., in response to detecting fault condition(s) in the power system or power loss from the power source 102), the capacitor voltage is determined and used to determine the power restoration delay time. The fault condition and/or loss of power source may be determined to be no longer present based on certain conditions and/or occurrences as discussed above with respect to FIG. 2A. Further, the capacitor voltage may be determined using techniques discussed above with respect to FIG. 2A.

In some embodiments, at step/operation 206, the controller 106 determines if the capacitor voltage is greater than a minimum threshold voltage (e.g., above about zero volts or the like). The controller 106 may determine if the capacitor voltage is greater than the minimum threshold voltage by comparing the capacitor voltage to the minimum threshold voltage. At step/operation 208A, if the controller 106 determines that the capacitor voltage is not greater than the minimum threshold voltage, the power restoration delay time is determined to be a predetermined delay time such as ten seconds, seven seconds, five seconds, or the like. In some example embodiments, the predetermined delay time is zero. It will be appreciated that the above examples of predetermined delay time are not intended to be limiting, and the predetermined delay time may be greater or less than the above examples. In some example embodiments, the predetermined delay time is configurable. At step/operation 208B, if the controller determines that the capacitor voltage is greater than the minimum threshold voltage, the power restoration delay time is determined to be the threshold delay time. At step/operation 210, the controller 106 waits the determined power restoration delay time before causing power to be restored to the electrical distribution system. At step/operation 212, the controller 106 may cause power to be restored to the electrical distribution system by driving a driver interface to drive a main contactor from an opened state to a closed state such that power supply to the electrical distribution system is no longer interrupted. At step/operation 214, the controller 106 may cause current to flow to the capacitor to recharge the capacitor. The controller 106 may cause current to flow to the capacitor by causing the switching device (e.g., bilateral switch or the like) coupled to the capacitor to switch from an OFF state to an ON state. In this regard, the controller 106 may cause the capacitor to recharge after the power restoration delay time has been elapsed and the power supply is stable (e.g., no faults).

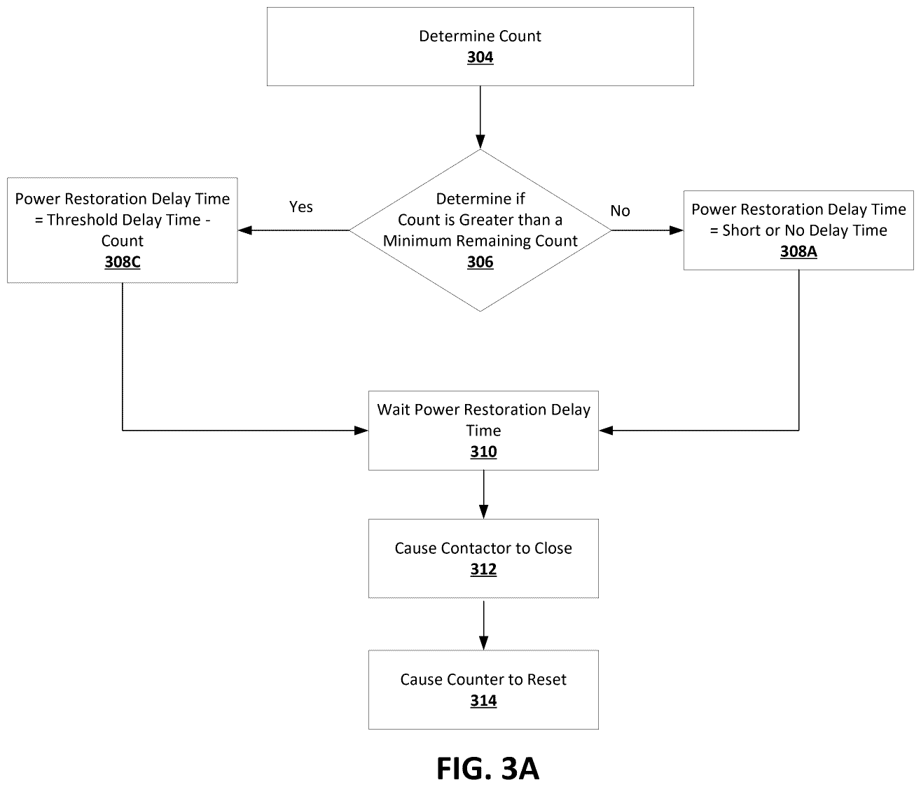

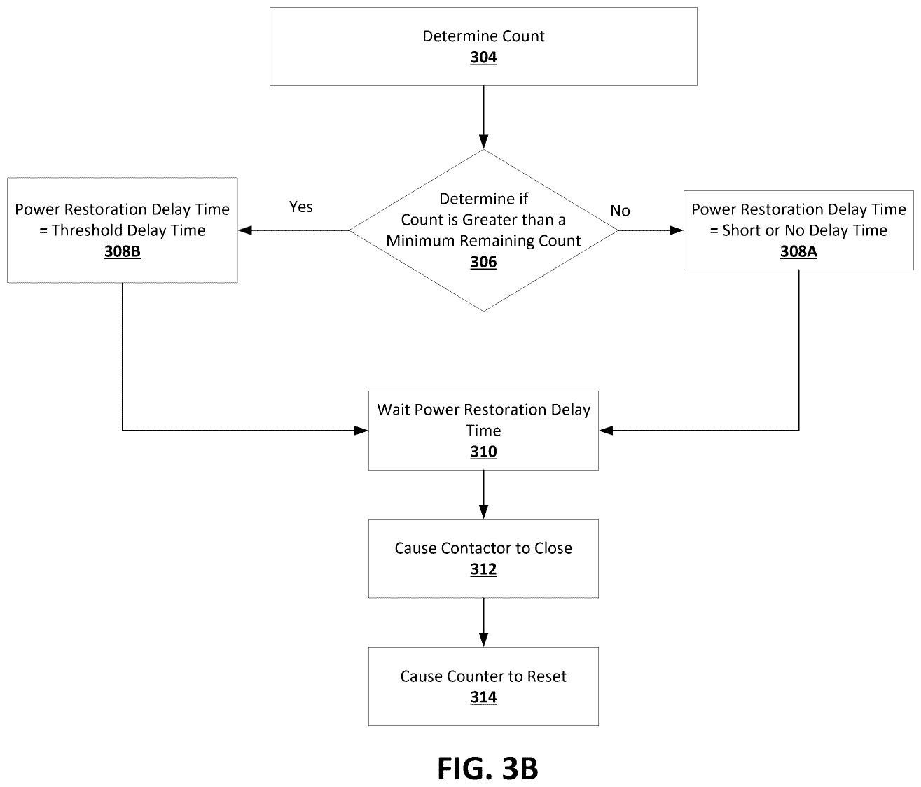

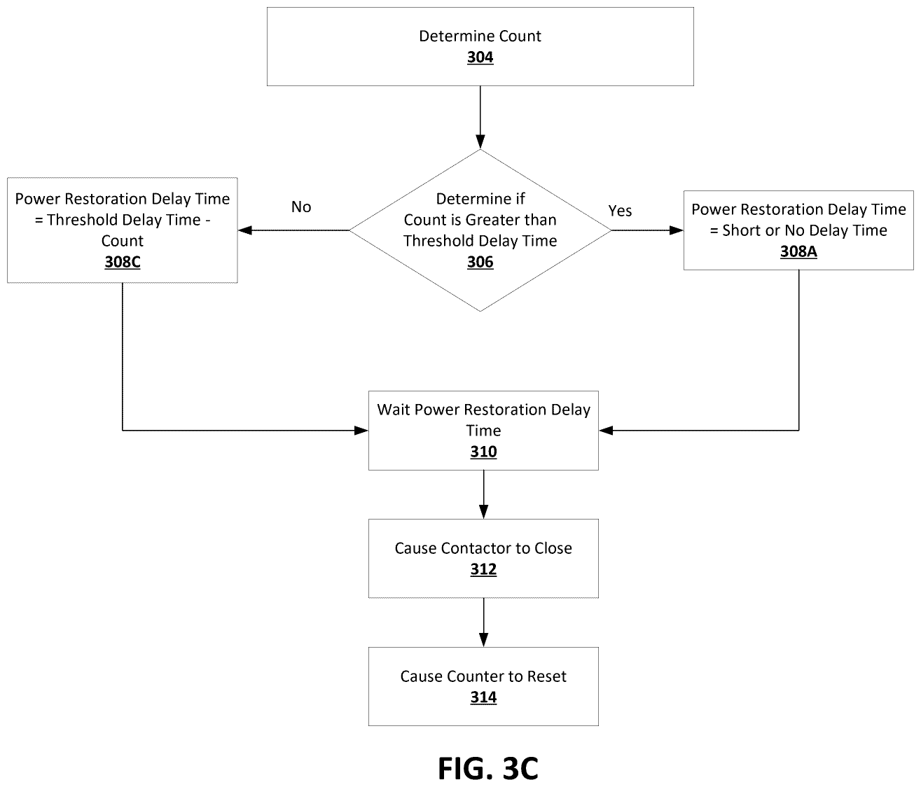

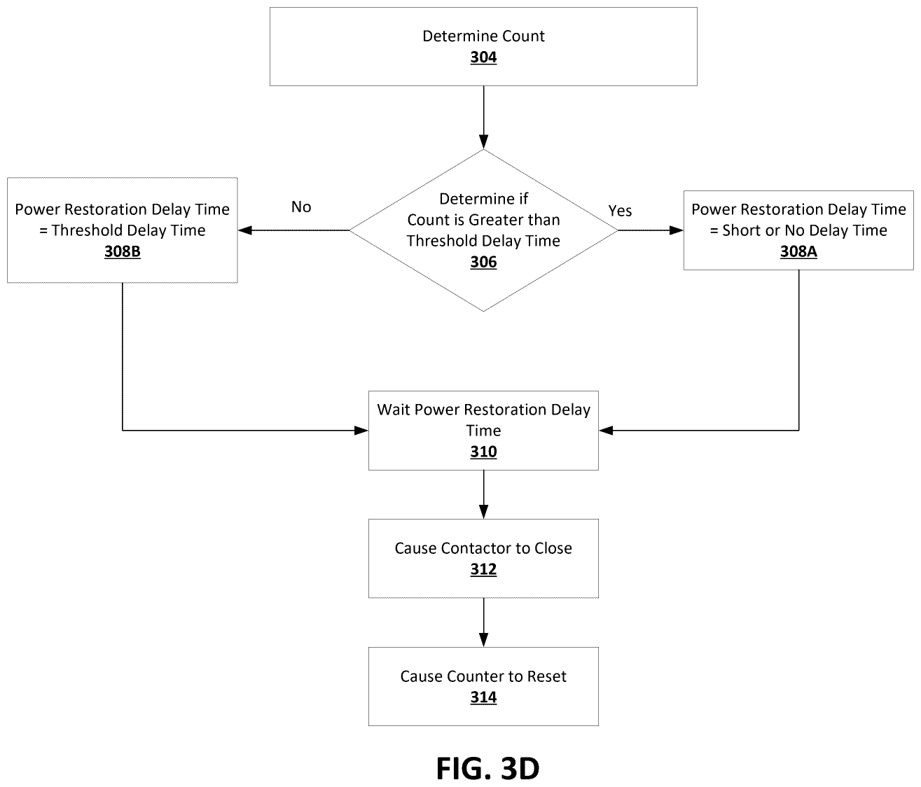

FIGS. 3A and 3B each show an example process flow for determining power restoration delay time for restoring power to an electrical distribution system using a timer circuit in accordance with at least some embodiments of the present disclosure. In some examples, the operations are performed utilizing a controller, such as controller 106.

In some embodiments, the delay time unit 108 includes a timer circuit. In some embodiments, the timer circuit may include a counter configured to count down when activated. In some embodiments, the counter may be configured to count up when activated. In some embodiments, the counter may be powered by a battery. In some embodiments, the counter may be powered by a capacitor. The controller 106 may be configured to cause the counter to count down (or count up in some embodiments) when power supplied to the electrical distribution system is interrupted.

As discussed below with respect to FIGS. 3A and 3B, in some embodiments, the controller 106 is configured to set the count on the counter to the maximum count and then when power to the electrical distribution system is interrupted, it causes the counter to begin counting down from the maximum count. In some embodiments, the controller is configured to set the count on the counter to the maximum count in response to power interruption and begin counting down from the maximum count. For example, the controller 106 may be configured to cause the main contactor to turn off (e.g., OFF state) in response to detecting a fault condition, set the counter to the maximum count, and cause the counter to begin counting down from the maximum count. In some embodiments, the maximum count corresponds to threshold delay time. The controller 106 may be configured to determine the power restoration delay time based on the remaining count (e.g., remaining time on the counter) when the fault condition is no longer present, loss of power source is no longer present, or otherwise power is applied to the one or more powered lines after power interruption (e.g., in response to detecting fault condition(s) in the power system or power loss from the power source 102). In some embodiments, a minimum remaining count (e.g., about zero remaining count or the like) indicates that the threshold delay time for restoring power to the electrical distribution system to prevent damage to the electrical distribution system and/or appliances supplied by the electrical distribution system, as described above, has been elapsed. In some embodiments, a remaining count that is greater than the minimum remaining count indicates that the minimum threshold delay time for restoring power to the electrical distribution system has not been elapsed, thus, additional delay time may be needed to elapse the minimum threshold delay time. In some embodiments, the counter may be configured to count up, and the count on the counter when the fault condition(s) are no longer present, loss of power source is no longer present, or otherwise power is applied to the one or more powered lines (e.g., after power interruption) is leveraged to determine the power restoration delay time.

As discussed below with respect to FIGS. 3C and 3D, in some embodiments, the controller 106 is configured to set the counter to a minimum count (e.g., about zero in some embodiments) and then when power to the electrical distribution system is interrupted, it causes the counter to begin counting up from the minimum count. In some embodiments, the controller is configured to set the count on the counter to the minimum count in response to power interruption and begin counting up from the minimum count. For example, the controller 106 may be configured to cause the main contactor to turn off (e.g., OFF state) in response to detecting a fault condition, set the counter to the minimum count and cause the counter to begin counting up from the minimum count. The controller 106 may be configured to determine the power restoration delay time based on the count on the counter when the fault condition is no longer present, loss of power source is no longer present, or otherwise power is applied to the one or more powered lines after power interruption (e.g., in response to detecting fault condition(s) in the power system or power loss from the power source 102).

Now referring to FIG. 3A, which is an example embodiment where the counter is configured to count down. In some embodiments, at step/operation 304, when the fault condition is no longer present (e.g., steady-state condition), loss of power source is no longer present, or otherwise power is applied to the one or more powered lines after power interruption, the remaining count on the counter is determined and used to determine the power restoration delay time. In some embodiments, at step/operation 306, the controller 106 determines if the remaining count is greater than the minimum remaining count. The controller 106 may determine if the remaining count is greater than the minimum remaining count by comparing the remaining count with the minimum remaining count. At step/operation 308A, If the controller 106 determines that the remaining count on the counter is not greater than the minimum remaining count, the power restoration delay time is determined to be a predetermined delay time such as ten seconds, seven seconds, five seconds, or the like. In some example embodiments, the predetermined delay time is zero. It will be appreciated that the above examples of predetermined delay time are not intended to be limiting, and the predetermined delay time may be greater or less than the above examples. In some examples, the predetermined delay time is configurable. At step/operation 308C, if the controller determines that the remaining count on the counter is greater than the minimum remaining count, the difference between the threshold delay time and remaining count is calculated (e.g., by the controller 106) to determine the power restoration delay time. The threshold delay time may correspond to the full count on the counter. At step/operation 310, the controller 106 waits the determined power restoration delay time before causing power to be restored to the electrical distribution system. At step/operation 312, the controller 106 may cause power to be restored to the electrical distribution system by driving a driver interface to drive a main contactor from an opened state to a closed state such that power supply to the electrical distribution system is no longer interrupted. At step/operation 314, the controller 106 may cause the counter to reset to the maximum count.

Now referring to FIG. 3B, which is another example embodiment where the counter is configured to count down. In such embodiments, at step/operation 304, when the fault condition is no longer present (e.g., steady-state), loss of power source is no longer present, or otherwise power is applied to the one or more powered lines after power interruption, the remaining count on the counter is determined and used to determine the power restoration delay time. In some embodiments, at step/operation 306, the controller 106 determines if the remaining count is greater than the minimum remaining count. The controller 106 may determine if the remaining count is greater than the minimum remaining count by comparing the remaining count with the minimum remaining count. In some embodiments, at step/operation 308A, if the controller 106 determines that the remaining count on the counter is not greater than the minimum remaining count, the power restoration delay time is determined to be a predetermined delay time such as ten seconds, seven second, five seconds, or the like. It will be appreciated that the above examples of predetermined delay time are not intended to be limiting, and the predetermined delay time may be greater or less than the above examples. In some embodiments, the predetermined delay time is configurable. At step/operation 308B, if the controller determines that the remaining count on the counter is greater than the minimum remaining count, the power restoration delay time is determined (e.g., by the controller 106) to be the threshold delay time. In some embodiments, at step/operation 310, the controller 106 waits the determined power restoration delay time before causing power to be restored to the electrical distribution system. In some embodiments, at step/operation 312, the controller 106 may cause power to be restored to the electrical distribution system by driving a driver interface to drive a main contactor from an opened state to a closed state such that power supply to the electrical distribution system is no longer interrupted. At step/operation 314, the controller 106 may cause the counter reset to the maximum count.

Now referring to FIG. 3C, which is an example embodiment where the counter is configured to count up. In some embodiments, at step/operation 304, when the fault condition is no longer present (e.g., steady-state condition), loss of power source is no longer present, or otherwise power is applied to the one or more powered lines after power interruption, the count on the counter is determined and used to determine the power restoration delay time. In some embodiments, at step/operation 306, the controller 106 determines if the count on the counter is greater than the threshold delay time. The controller 106 may determine if the count on the counter is greater than the minimum remaining count by comparing the count on the counter with the threshold delay time. At step/operation 308A, If the controller 106 determines that the count on the counter is greater than the threshold delay time, the power restoration delay time is determined to be a predetermined delay time such as ten seconds, seven seconds, five seconds, or the like. In some example embodiments, the predetermined delay time is zero. It will be appreciated that the above examples of predetermined delay time are not intended to be limiting, and the predetermined delay time may be greater or less than the above examples. In some examples, the predetermined delay time is configurable. At step/operation 308C, if the controller determines that the count on the counter is not greater than the threshold delay time, the difference between the threshold delay time and the count on the counter is calculated (e.g., by the controller 106) to determine the power restoration delay time. At step/operation 310, the controller 106 waits the determined power restoration delay time before causing power to be restored to the electrical distribution system. At step/operation 312, the controller 106 may cause power to be restored to the electrical distribution system by driving a driver interface to drive a main contactor from an opened state to a closed state such that power supply to the electrical distribution system is no longer interrupted. At step/operation 314, the controller 106 may cause the counter to reset to the minimum count.

Now referring to FIG. 3D, which is another example embodiment where the counter is configured to count up. In such embodiments, at step/operation 304, when the fault condition is no longer present (e.g., steady-state), loss of power source is no longer present, or otherwise power is applied to the one or more powered lines after power interruption, the count on the counter is determined and used to determine the power restoration delay time. In some embodiments, at step/operation 306, the controller 106 determines if the count is greater than the threshold delay time. The controller 106 may determine if the count on the counter is greater than the threshold delay time count by comparing the count on the counter with the threshold delay time. In some embodiments, at step/operation 308A, if the controller 106 determines that the count on the counter is greater than the threshold delay time, the power restoration delay time is determined to be a predetermined delay time such as five seconds or less. At step/operation 308B, if the controller determines that the count on the counter is not greater than the threshold delay time, the power restoration delay time is determined (e.g., by the controller 106) to be the threshold delay time. In some embodiments, at step/operation 310, the controller 106 waits the determined power restoration delay time before causing power to be restored to the electrical distribution system. In some embodiments, at step/operation 312, the controller 106 may cause power to be restored to the electrical distribution system by driving a driver interface to drive a main contactor from an opened state to a closed state such that power supply to the electrical distribution system is no longer interrupted. At step/operation 314, the controller 106 may cause the counter to reset to the minimum count.

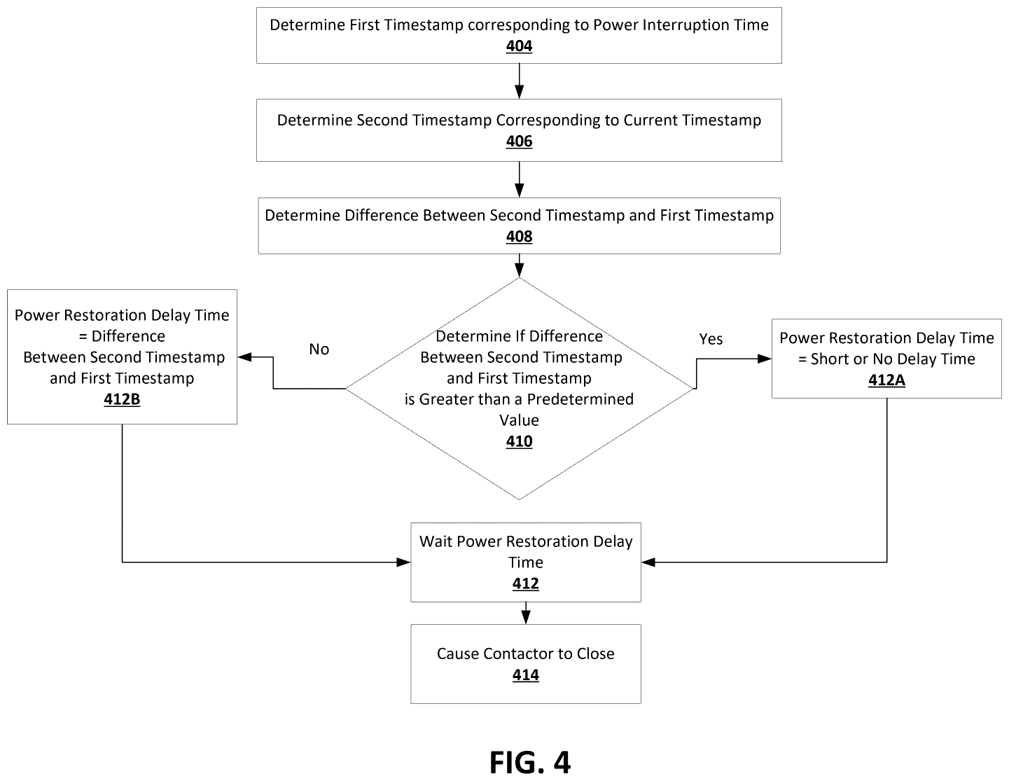

FIG. 4 shows an example process flow for determining power restoration delay time for restoring power to an electrical distribution system using a clock in accordance with at least some embodiments of the present disclosure. In some embodiments, the delay time unit 108 includes a clock (e.g., a real-time clock). In some embodiments, the clock may be powered by a battery. In some embodiments, the clock may be powered by a capacitor. The controller 106, using, the clock, may be configured to determine a first timestamp corresponding to the time when power supplied to the electrical distribution system is interrupted. The controller may be configured to store the first timestamp in a memory. For example, the controller 106 may be configured to cause the main contactor to turn off (e.g., OFF state) in response to detecting a fault condition, determine the first timestamp corresponding to when the main contactor was caused to turn off, and store the first timestamp in memory. The controller 106, using the clock, may be configured to determine a second timestamp corresponding to when the fault condition is no longer present, and determine the power restoration delay time based on the difference between the second timestamp and the first timestamp. For example, the controller 106 may be configured to calculate the difference between the second timestamp and the first timestamp in response to determining that the fault condition(s) is no longer present, that loss of power source is no longer present, or otherwise that power is applied to the one or more power lines after power interruption.

As described above, FIG. 4 shows an example process flow for determining power restoration delay time for restoring power to an electrical distribution system using a clock in accordance with at least some embodiments of the present disclosure. In some examples, the operations are performed utilizing a controller, such as controller 106. In some embodiments, at step/operation 404, when the fault condition is no longer present, loss of power source is no longer present, or otherwise power is applied to the one or more powered lines after power interruption (e.g., in response to detecting fault condition(s) in the power system or power loss from the power source 102), the controller 106 may retrieve (e.g., from memory) data that comprise the first timestamp corresponding to when power supply to the electrical distribution system was interrupted. In this regard, the controller 106 may be configured to determine when the fault condition is no longer present, when loss of power source is no longer present, or otherwise when power is applied to the one or more powered lines after power interruption and in response, retrieve the data comprising the first timestamp. At step/operation 406, the controller 106, using the clock, may be configured to determine a second timestamp (e.g., current timestamp) corresponding to the time when the fault condition is no longer present, the time when loss of power source is no longer present, or otherwise the time when power is applied to the one or more powered lines after power interruption. In some embodiments, at step/operation 408, the controller 106 may be configured to determine the difference between the second timestamp and the first timestamp. For example, the controller 106 may be configured to calculate the difference between the second timestamp and the first timestamp.

In some embodiments, at step/operation 410, the controller 106 determines if the difference between the second timestamp and the first timestamp is greater than a predetermined value. In various embodiments, the predetermined value is the threshold delay time, as described above. The controller 106 may determine if the difference between the second timestamp and the first timestamp is greater than the predetermined value (e.g., threshold delay time) by comparing the difference between the second timestamp and the first timestamp with the predetermined value. In some embodiments, at step/operation 412A, if the controller 106 determines that the difference between the second timestamp and the first timestamp is greater the predetermined value, the power restoration delay time is determined to be a predetermined delay time such as ten seconds, seven seconds, five seconds, or the like. In some example embodiments, the predetermined delay time is zero. It will be appreciated that the above examples of predetermined delay time are not intended to be limiting, and the predetermined delay time may be greater or less than the above examples. In some examples, the predetermined delay time is configurable. At step/operation 412B, if the controller determines that the difference between the second timestamp and the first timestamp is not greater than the predetermined value, the power restoration delay time is determined to be the difference between the second timestamp and the first timestamp. At step/operation 412, the controller 106 waits the determined power restoration delay time before causing power to be restored to the electrical distribution system. At step/operation 414, the controller 106 may cause power to be restored to the electrical distribution system by driving a driver interface to drive a main contactor from an opened state to a closed state such that power supply to the electrical distribution system is no longer interrupted.

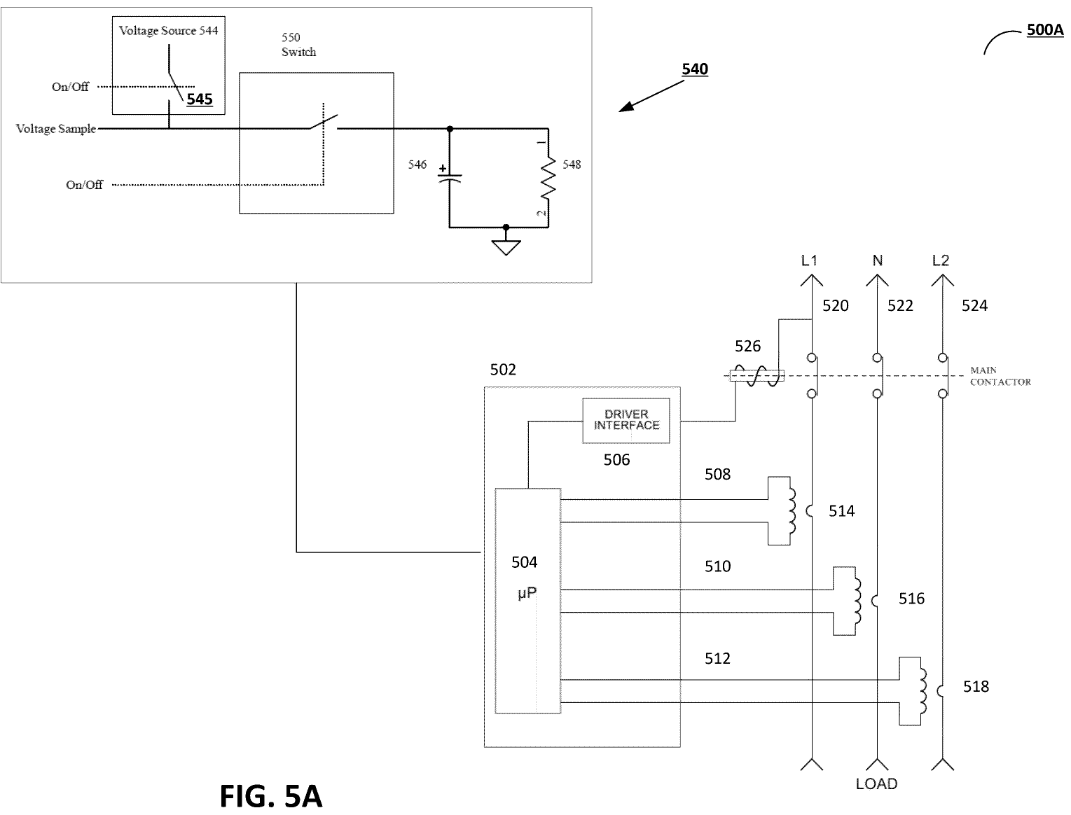

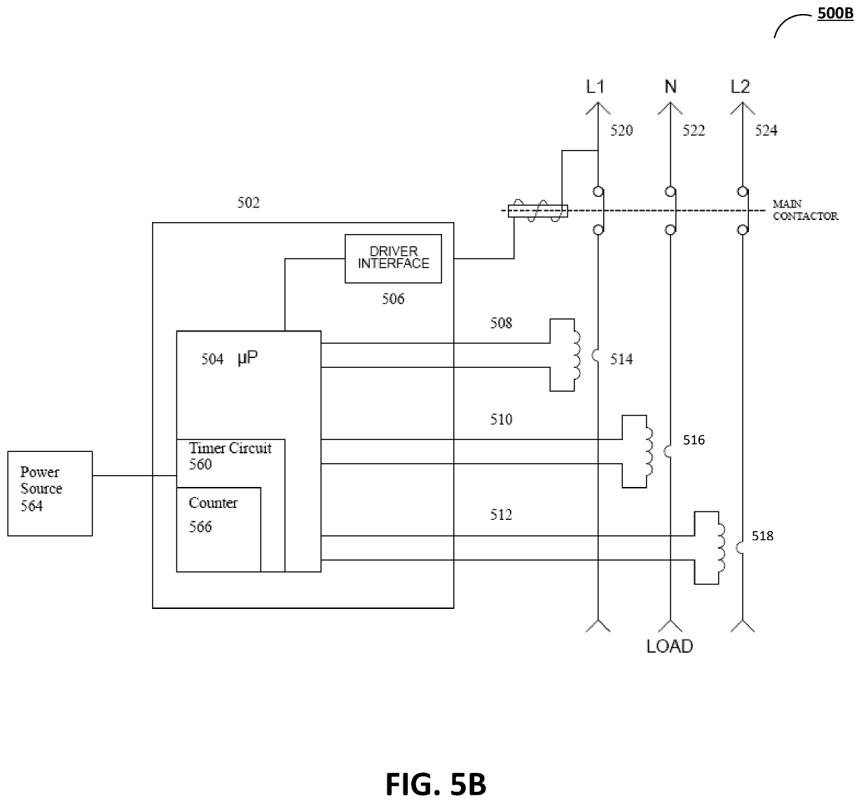

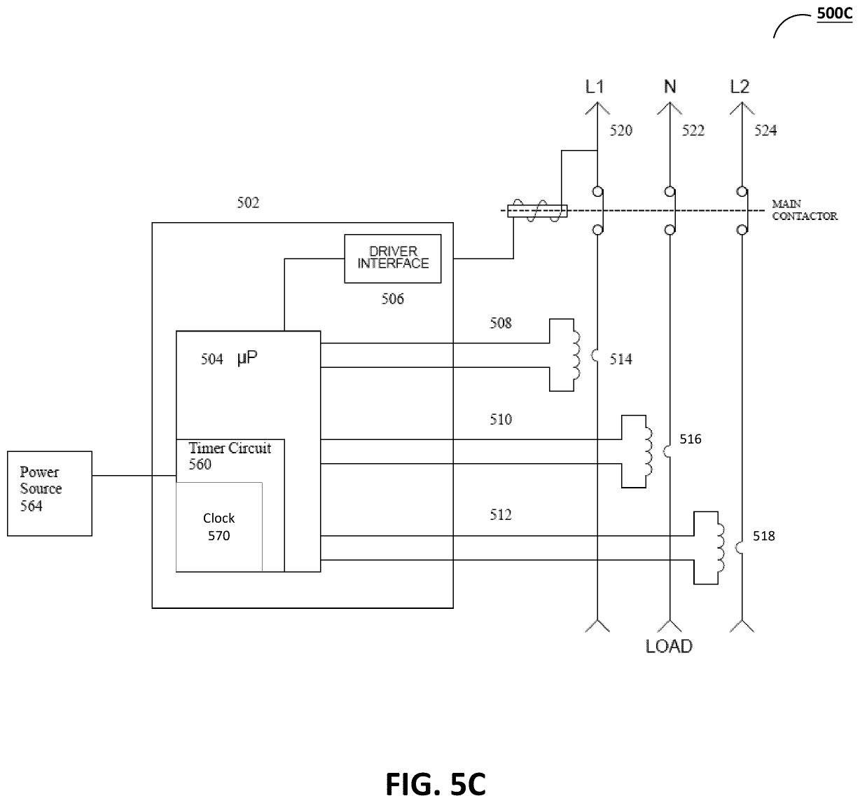

FIGS. 5A-C each, respectively, show a schematic diagram of an apparatus 500A, 500B, and 500C for detecting fault conditions and restoring power to the electrical distribution system after interruption of power supply to the electrical distribution system in accordance with at least some embodiments of the present disclosure. The depiction of the apparatuses 500A, 500B, and 500C is not intended to limit or otherwise confine the embodiments described and contemplated herein to any particular configuration nor is it intended to exclude any alternative configuration that can be used in connection with embodiments of the present disclosure. In particular, while the depicted apparatuses 500A, 500B, and 500C include two powered lines and a shared neutral line corresponding to a split-phase power system, in other embodiments, the apparatuses 500A, 500B, and 500C include one powered line and a neutral line.

Now referring to FIG. 5A, in the illustrated embodiment, the apparatus 500A includes a controller 502. The controller 502 includes a microprocessor 504 and a driver interface 506. In some examples, microprocessor 504 is connected to transformers such as transformers 514, 516, and 518 through connections 508, 510, and 512. Transformer 514 is configured to measure the current of a first powered line in a power system, such as line 520. Transformer 518 is configured to measure the current of a second powered line in the power system, such as line 524. Transformer 516 is configured to measure the current of a neutral line in the power system, such as line 522. In some examples, the microprocessor 504 is configured to determine if a fault condition is present based on one or more of the measured currents from transformers 514, 516, and 518. While the apparatus 500A is depicted as including three transformers, in some embodiments, the apparatus 500A may include more or less transformers. For example, in some embodiments, the apparatus 500A may include two transformers with one transformer configured to measure the current on the first powered line and the other transformer configured to measure the current on the second powered line, wherein a fault condition is detected based on one or more of the measured currents on the first powered line or the second powered line. As another example, in some embodiments, the apparatus 500A may include two transformers with one transformer configured to measure the current on one powered line and the other transformer is configured to measure the current on the neutral line, wherein a fault condition is detected based on one or more of the measured currents on the powered line or the neutral line.

Additionally, according to various embodiments, the microprocessor 504 is connected to a resistive-capacitive circuit 540 comprising a voltage source 544, a capacitor 546, a resistor 548, and a switching device 550. As shown in FIG. 5A, the voltage source may include or is otherwise coupled to a switching device 545 configured for switching the voltage source 544 between an ON state and an OFF state. According to various embodiments, when the switching device 550 is in an ON state and the capacitor 546 is not fully charged, current will flow from the voltage source 544 through the capacitor 546, and the capacitor 546 will store voltage. In some embodiments, the capacitor 546 and the resistor 548 may be selected such that the capacitor 546 charges quickly to a full charge when the switching device 550 and voltage source 544 are in an ON state and discharges slowly through the resistor 548 when the switching device 550 is an OFF state. For example, the capacitor 546 may charge up to the voltage of the voltage source when the switching device 550 and voltage source 544 are in an ON state.

In the example embodiments, the resistor 548 may be configured to discharge the capacitor for a time measurement. However, it will be appreciated that in some embodiments, this can be any constant current sink or current limiting device. In various embodiments, for the time measurement, the current may be sourced from the capacitor in a controlled manner, which can be done with a resistor, constant current sink, and/or the like.

According to various embodiments, if the microprocessor 504 determines a fault condition is present, the microprocessor 504 will drive a driver interface, such as driver interface 506, to interrupt power supply to the electrical distribution system. In some example embodiments, driver interface 506 will drive a main contactor, such as main contactor 526, to interrupt the powered lines 520 and 524. In some examples, driver interface 506 may interrupt power source 102 connected to the apparatus 500A. While illustrated in FIG. 5A as a component of the apparatus 500A, the main contactor 526 (the interrupter) may comprise a device remote from the apparatus 500A and configured to receive a signal from the apparatus 500A.

Additionally, according to various embodiments, when power to the electrical distribution system is interrupted, the microprocessor 504 will cause the capacitor 546 to start discharging the voltage stored by the capacitor 546 by causing the switching device 550 to switch from an ON state to an OFF state. According to various embodiments, if the microprocessor 504 determines that the fault condition(s) is no longer present or otherwise power is applied to the powered lines, the microprocessor 504 will determine a power restoration delay time for restoring power to the electrical distribution system in accordance with the operation/steps described with reference to FIG. 2A or FIG. 2B.

Now referring to FIG. 5B, in the illustrated embodiment, the apparatus 500B includes a controller 502. The controller 502 includes a microprocessor 504 and a driver interface 506. In some examples, microprocessor 504 is connected to transformers such as transformers 514, 516, and 518 through connections 508, 510, and 512. Transformer 514 is configured to measure the current of a first powered line in a power system, such as line 520. Transformer 518 is configured to measure the current of a second powered line in the power system, such as line 524. Transformer 516 is configured to measure the current of a neutral line in the power system, such as line 522. In some examples, the microprocessor 504 is configured to determine if a fault condition is present from the measured currents from transformers 514, 516, and 518. While the apparatus 500B is depicted as including three transformers, in some embodiments, the apparatus 500B may include more or less transformers. For example, in some embodiments, the apparatus 500B may include two transformers with one transformer configured to measure the current on the first powered line and the other transformer configured to measure the current on the second powered line, wherein a fault condition is detected based on one or more of the measured currents on the first powered line or the second powered line. As another example, in some embodiments, the apparatus 500B may include two transformers with one transformer configured to measure the current on one powered line and the other transformer is configured to measure the current on the neutral line, wherein a fault condition is detected based on one or more of the measured currents on the powered line or the neutral line.

According to various embodiments, the microprocessor 504 includes a timer circuit 560 comprising a counter 566. For example, the microprocessor 504 may include a counter 566 integrated therein. In some embodiments, the microprocessor 504 may include a power input (e.g., a separate power input input) configured for running the counter 566. The microprocessor 504, for example, may operate on low power with respect to the counter 566, which can be run from the power source or a capacitor (e.g., a small capacitor type). For example, the timer circuit 560 and/or or the counter 566 may be coupled to a power source 564 such as a battery, a capacitor, or other suitable power source configured to power the counter 566. According to various embodiments, the counter 566 may be configured to count down from a threshold delay time when triggered. According to some other embodiments, the counter 566 may be configured to count up to a threshold delay time when triggered. According to various embodiments, if the microprocessor 504 determines a fault condition is present, the microprocessor 504 will drive a driver interface, such as driver interface 506, to interrupt power supply to the electrical distribution system. In some example embodiments, driver interface 506 will drive a main contactor, such as main contactor 526, to interrupt the powered lines 520 and 524. In some examples, driver interface 506 may interrupt power source 102 connected to the apparatus 500B. While illustrated in FIG. 5B as a component of the apparatus 500B, the main contactor 526 may comprise a device remote from the apparatus and configured to receive a signal from the apparatus 500B.

Additionally, according to various embodiments, when power supply to the electrical distribution system is interrupted, the microprocessor 504 will cause the counter 566 to start counting down (or counting up in some embodiments). In some embodiments, the microprocessor 504 may send signals, data, instructions, and/or the like to trigger the counter 566 to start counting down (or counting up in some embodiments). In some embodiments, the microprocessor 504 may drive a driver interface, such as driver interface 506, to cause the counter to start counting down (or counting up in some embodiments). According to various embodiments, if the microprocessor 504 determines that the fault condition(s) is no longer present or otherwise power is applied to the powered lines, the microprocessor 504 will determine a power restoration delay time for restoring power to the electrical distribution system in accordance with the operation/steps described with reference to FIG. 3A or FIG. 3B.

Now referring to FIG. 5C, in the illustrated embodiment, the apparatus 500C includes a controller 502. The controller 502 includes a microprocessor 504 and a driver interface 506. In some examples, microprocessor 504 is connected to transformers such as transformers 514, 516, and 518 through connections 508, 510, and 512. Transformer 514 is configured to measure the current of a first powered line in a power system, such as line 520. Transformer 518 is configured to measure the current of a second powered line in the power system, such as line 524. Transformer 516 is configured to measure the current of a neutral line in the power system, such as line 522. In some examples, the microprocessor 504 is configured to determine if a fault condition, such as an open neutral condition, is present from the measured currents from transformers 514, 516, and 518. While the apparatus 500C is depicted as including three transformers, in some embodiments, the apparatus 500C may include more or less transformers. For example, in some embodiments, the apparatus 500C may include two transformers with one transformer configured to measure the current on the first powered line and the other transformer configured to measure the current on the second powered line, wherein a fault condition is detected based on one or more of the measured currents on the first powered line or the second powered line. As another example, in some embodiments, the apparatus 500C may include two transformers with one transformer configured to measure the current on one powered line and the other transformer is configured to measure the current on the neutral line, wherein a fault condition is detected based on one or more of the measured currents on the powered line or the neutral line.

According to various embodiments, the microprocessor 504 includes a timer circuit 560 comprising a clock 570. For example, the microprocessor 504 may include a clock 570 integrated therein. In some embodiments, the microprocessor 504 may include a power input (e.g., a separate power input input) configured for running the clock 570. The microprocessor 504, for example, may operate on low power with respect to the clock 570, which can be run from the power source or a capacitor (e.g., a small capacitor type). For example, the timer circuit 560 and/or the clock 570 may be coupled to a power source 564 such as a battery, a capacitor, or other suitable power source configured to power the clock 570. The clock 570 may comprise a real-time clock configured for determining the current time. According to various embodiments, if the microprocessor 504 determines a fault condition is present, the microprocessor 504 will drive a driver interface, such as driver interface 506, to interrupt power supply to the electrical distribution system. In some example embodiments, driver interface 506 will drive a main contactor, such as main contactor 526, to interrupt the powered lines 520 and 524. In some examples, driver interface 506 may interrupt power source 102 connected to the apparatus 500C. While illustrated in FIG. 5C as a component of the apparatus 500C, the main contactor 526 may comprise a device remote from the apparatus and configured to receive a signal from the apparatus 500C.

Additionally, according to various embodiments, when power supply to the electrical distribution is interrupted, the microprocessor 504 will determine the time the power supply was interrupted (e.g., first timestamp). According to various embodiments, if the microprocessor 504 determines that the fault condition(s) is no longer present, determines that loss of power source is no longer present, or otherwise determines that power is applied to the one or more powered lines after power interruption, the microprocessor 504 will determine the time the current the fault conditions(s) is no longer present (e.g., second timestamp), the time the loss of power source is no longer present, or otherwise the time the power is applied to the one or more powered line after power interruption. The microprocessor 504 may then determine a power restoration delay time for restoring power to the electrical distribution system in accordance with the operation/steps described with reference to FIG. 4.

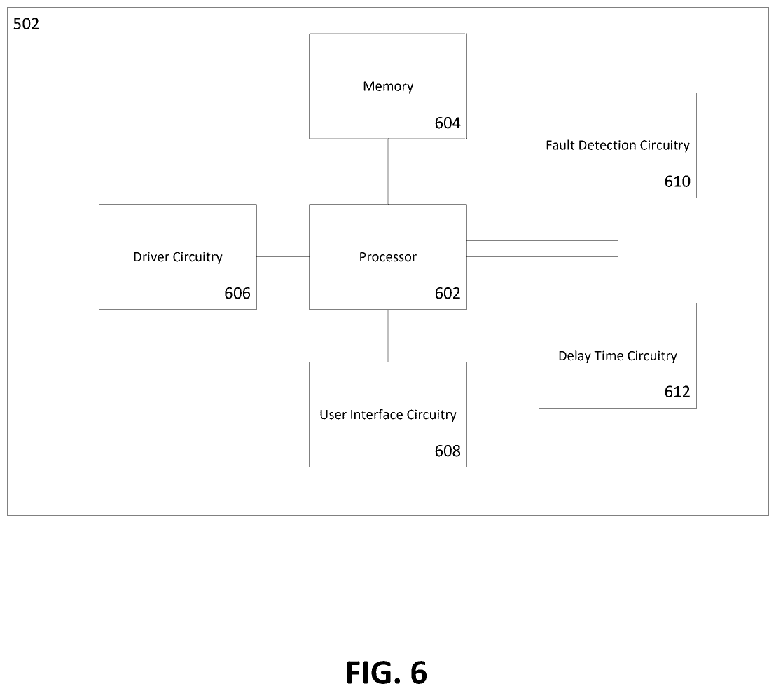

FIG. 6 shows an exemplary block diagram of a fault detector controller 502 according to at least some embodiments of the present disclosure. In the illustrated embodiment, controller 502 includes a processor 602, memory 604, driver circuitry 606, user interface circuitry 608, fault detection circuitry 610, and delay timer circuitry 612. In some examples, processor 602 is embodied as a microprocessor 504. As shown, memory 604 is configured to store software or firmware configured to provide instructions, such as computer instructions or computer code, in conjunction with processor 602 and circuitries 606, 608, 610, and 612 to determine if a fault condition is present in fault detector, such as fault detector 104, interrupt power to an electrical distribution system when a fault condition is detected, determine a power restoration delay time when power to the electrical distributions system is interrupted, and restore power to the electrical distribution system. In some examples, driver circuitry 606 is configured to drive a main contactor, such as main contactor 526, to interrupt a power source in a power system. In some examples, user interface circuitry 608 is configured to provide an indication to a user that a fault condition is present in the power system. For example, user interface circuitry 608 may indicate a fault condition on a liquid crystal display (LCD) screen or may be configured to light a light emitting diode (LED) light to indicate to a user that a fault condition is present in a power system.

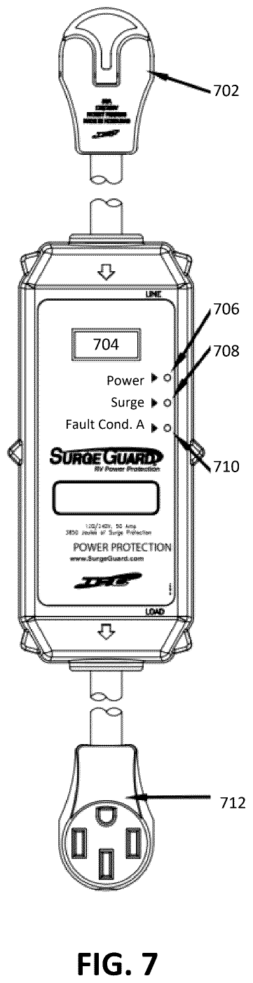

FIG. 7 shows an example application embodiment of surge protector, such as surge protector 700, according to at least some embodiments of the present disclosure. In the illustrated embodiment, surge protector 700 comprises a power source 702, output power 712, and user interface components including LCD screen 704 and LED indicator lights 706, 708, and 710. In some examples, a fault detector such as fault detector 104, controller such as controller 106, and/or delay time unit such as delay time unit 108, are embodied in a surge protector 700 and utilizes power source 702 as power source 102 and outputs output power 110 as output power 712. In an example embodiment, user interface components, such as an LCD screen 704 and LED indicator lights 706, 708, and 710 indicate various functions of the surge protector 700, such as power on, surge detected, fault condition detected, etc. In some examples, the user interface components are configured to indicate to a user that a fault condition is present. For example, LCD screen 704 may indicate or read out a fault condition detected, or LED indicator light 710 may light up if certain fault conditions are present.

In one embodiment, power source 702 is a plug configured to plug into a 50 A RV service power pedestal. Furthermore, output power 712 is a plug configured to accept a 50 A rated plug from an RV power distribution system. For example, the power source plug may be configured for being mated to a power pedestal and the output power plug configured to accept an input power plug from an RV power distribution system.

In some embodiments, the power restore functionalities described herein may be turned on or off via an application such as the surge protector application. Alternatively or additionally, the power restore functionalities described herein may be turned on or off via a button or the like on the surge protector 700. Additionally, the surge protector 700 may include a button or the like configured to turn the surge protector 700 on or off.

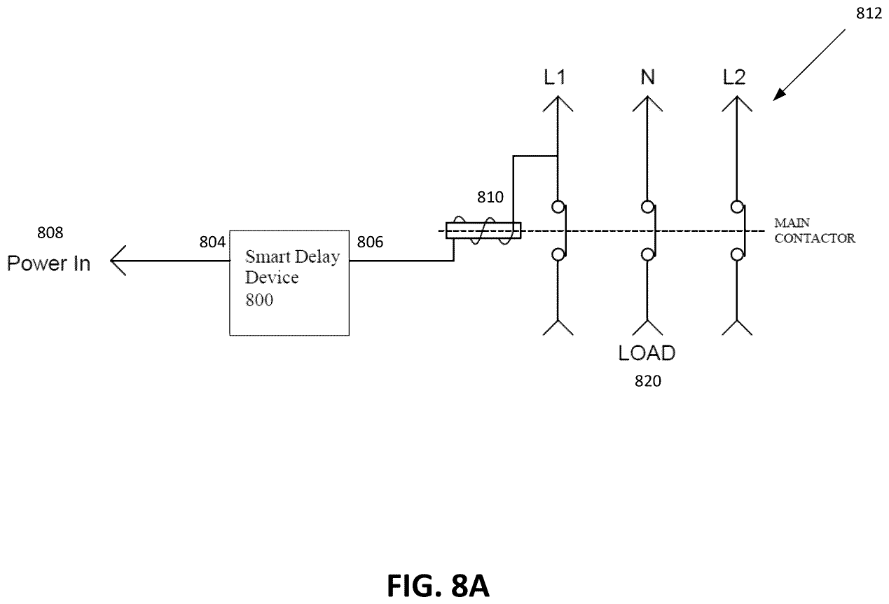

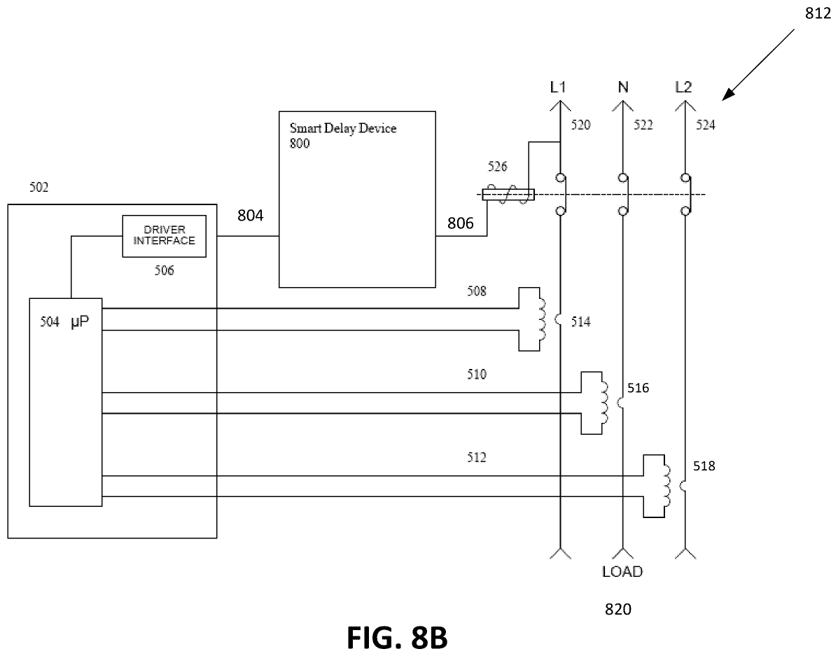

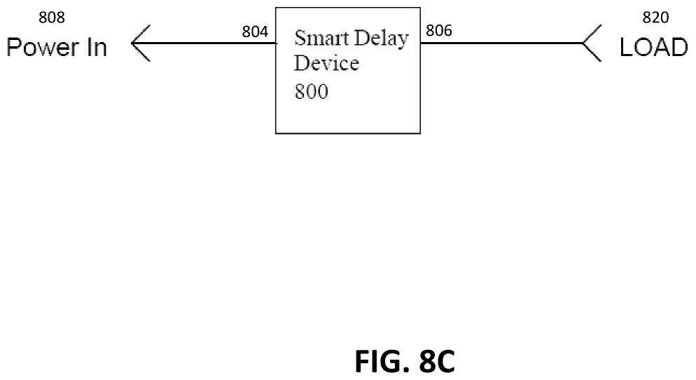

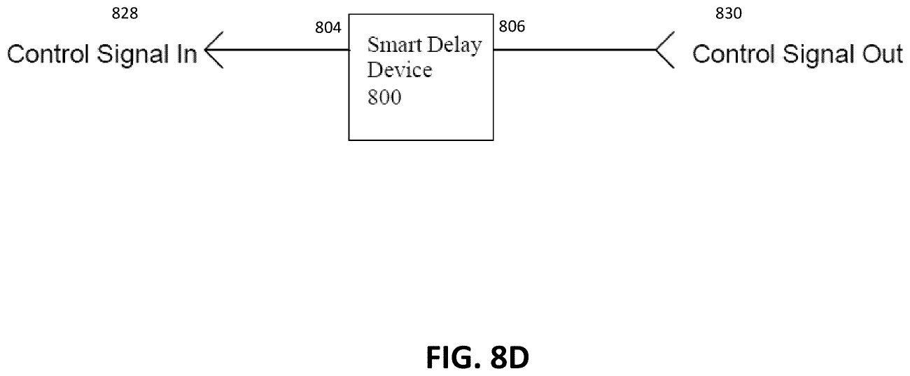

FIGS. 8A-8D each show a schematic diagram of a smart delay device 800 in accordance with at least one embodiment of the present disclosure. The smart delay device 800 includes a smart delay circuitry comprising a delay time unit (e.g., such as delay time unit 108 described above with respect to FIG. 1) and/or a controller. The controller may include a processor, microprocessor, or the like configured for performing one or more functionalities of the smart delay device 800. In some embodiments, the controller may comprise controller 106 described above with respect to FIG. 1.

The smart delay device 800 may be a stand-alone device that can be coupled to, integrated within, or otherwise utilized in any of a variety of devices, equipment, and/or systems (e.g., fault detector systems, fault detectors, surge protectors, equipment (e.g., refrigerators, air conditioning units, and/or the like), transfer switches, or the like). As shown in FIGS. 8A-8D, the smart delay device 800 includes an input component 804 and an output component 806. In some embodiments, the input component comprises one or more input terminals. In some embodiments, the output component comprises one or more output terminals.

In some embodiments, the input component 804 is configured for being connected to a power source such that it may receive input power 808 from a power source. The power source may be configured to provide a single-phase power, three-phase power, split phase power, or the like to an electrical distribution system, device, equipment, and/or the like. In some embodiments, the input component 804 is configured for being connected to a control signal source such that it may receive an input control signal 828 from the control input source. The control signal source, for example, may be configured for controlling a contactor, relay, and/or the like of an equipment (e.g., refrigerator, air conditioning unit, or the like).

According to various embodiments, the smart delay device 800 is configured to perform the steps/operations (or portion thereof) described in at least one of FIG. 2A, 2B, 3A, 3B, 3C, 3D, or 4. Specifically, the smart delay device 800 is configured to calculate or otherwise determine power restoration delay time for a device, equipment, electrical distribution system, or the like by performing the steps/operations (or portion thereof) described in at least one of FIG. 2A, 2B, 3A, 3B, 3C, 3D, or 4.

In some embodiments, the smart delay device 800 includes a resistive-capacitive circuit such as resistive-capacitive circuit 540 described above with respect to FIG. 5A. The resistive-capacitive circuit 540 may include a voltage source 544, a capacitor 546, a resistor 548, and/or a switching device 550. Additionally, the smart delay device 800 may include a controller coupled to the resistive-capacitive circuit 540 or otherwise associated with the resistive-capacitive circuit 540. For example, in some embodiments, the smart delay device 800 may include a smart delay circuitry comprising a resistive-capacitive circuit 540 and a controller. According to various embodiments, the controller is configured to perform the steps/operations (or portion thereof) described in at least one of FIG. 2A, 2B, 3A, 3B, 3C, 3D, or 4 based on the resistive-capacitive circuit 540.

In some embodiments, the smart delay device 800 includes a timer circuit such as timer circuit 560, described above with reference to FIGS. 5B and 5C. In some embodiments, the timer circuit 560 includes a counter such as counter 566 described above with respect to FIG. 5B. In some embodiments, the timer circuit includes a clock such as clock 570 described above with respect to FIG. 5B. In some embodiments, the smart delay device 800 includes a controller coupled to the counter 566 or otherwise associated with the counter 566. For example, in some embodiments, the smart delay device 800 may include a smart delay circuitry comprising a timer circuit 560 and a controller. In an example embodiment, the controller embodies the timer circuit 560. For example, the timer circuit 560 may be integrated within the controller. According to various embodiments, the controller is configured to perform the steps/operations (or portion thereof) described in at least one of FIG. 2A, 2B, 3A, 3B, 3C, 3D, or 4 based on the timer circuit 560.

In the illustrated example smart delay device 800 of FIG. 8A, the input component 804 is configured for being connected to a power source and the output component 806 is configured for being connected to a main contactor 810 such that the smart delay device 800 drives the main contactor 810 in accordance with a power restoration delay time determined by the smart delay device 800. The power source may be configured for supplying power to an electrical distribution system 812. The main contactor 810 may be configured to facilitate selective supply of power, from the power source, to the electrical distribution system 812. As shown in FIG. 8A, the electrical distribution system 812 may be configured to deliver power (e.g., received from the power source) to one or more loads 820 (e.g., a refrigerator, air conditioning unit, and/or the like). The electrical distribution system may be a residential electrical distribution system, commercial electrical distribution system, or the like.

The input component 804 may be configured to receive input power 808 supplied by the power source. In response to receiving the input power after a power loss or otherwise interruption of power supplied by the power source, the controller may perform the steps/operations (or portion thereof) described in at least one of FIG. 2A, 2B, 3A, 3B, 3C, 3D, or 4 to determine the power restoration delay time and drive the main contactor 810 in accordance with the power restoration delay time.

According to various embodiments, in response to power being applied following interruption of power supplied by the power source, the smart delay device 800 may delay power supply to the electrical distribution system based on the power restoration time calculated or otherwise determined by the smart delay device 800. In an example embodiment, in response to power being applied, the smart delay device 800 waits for a duration of time corresponding to the power restoration time and then transmits a signal to the main contactor 810. According to various embodiments, the transmitted signal is configured to cause the main contactor 810 to move from an opened state to a closed state such that power from the power source may be supplied to the electrical distribution system 812 after the power restoration time is elapsed.

In some embodiments, such as shown in FIG. 8B, the smart delay device 800 may be integrated within a surge protector or a fault detector. As shown in FIG. 8B, the input component 804 of the illustrated example smart delay device 800 is configured for being connected to a microprocessor 504 component of a surge protector or fault detector. The output component 806 of the illustrated example smart delay device 800 of FIG. 8B is configured for being connected to a main contactor 526 such that the smart delay device 800 drives the main contactor 526 in accordance with a power restoration delay time determined by the smart delay device 800. The main contactor 526, for example, may be configured to facilitate selective supply of power, from the power source to the electrical distribution system 812.

The input component 804 may be configured to receive input signal from the microprocessor 504, The input signal may be indicative of the power supply status of the power source configured to supply power to the electrical distribution system 812. For example, in response to receiving input signal from the microprocessor 504 that indicates that power is being applied after loss of power or otherwise interruption of power supplied by the power source, the controller may perform the steps/operations (or portion thereof) described in at least one of FIG. 2A, 2B, 3A, 3B, 3C, 3D, or 4 to determine the power restoration delay time and drive the main contactor 526 in accordance with the power restoration delay time.

According to various embodiments, in response to power being applied following interruption of power supplied by the power source, the smart delay device 800 may delay power supply to the electrical distribution system 812 based on the power restoration time calculated or otherwise determined by the smart delay device 800. In an example embodiment, in response to power being applied, the smart delay device 800 waits for a duration of time corresponding to the power restoration time and then transmits a signal to the main contactor 526. According to various embodiments, the transmitted signal is configured to cause the main contactor 526 to move from an opened state to a closed state such that power from the power source may be supplied to the electrical distribution system 812 after the power restoration time is elapsed.

In the illustrated example smart delay device of FIG. 8C, the input component 804 is configured for being connected to a power source and the output component 806 is configured for being connected to one or more loads 820 (e.g., a refrigerator, air conditioning unit, or the like) such that the smart delay device 800 drives the one or more loads 820 in accordance with a power restoration delay time determined by the smart delay device 800. The power source may be configured for supplying power to the one or more loads 820.

The input component 804 of the smart delay device 800 may be configured to receive input power 808 supplied by the power source. In response to receiving the input power after a power loss or otherwise interruption of power supplied by the power source, the controller may perform the steps/operations (or portion thereof) described in at least one of FIG. 2A, 2B, 3A, 3B, 3C, 3D, or 4 to determine the power restoration delay time and drive the main contactor 810 in accordance with the power restoration delay time.

According to various embodiments, in response to power being applied following interruption of power supplied by the power source, the smart delay device 800 may delay power supply to the one or more loads 820 based on the power restoration time calculated or otherwise determined by the smart delay device 800. In an example embodiment, in response to power being applied, the smart delay device 800 waits for a duration of time corresponding to the power restoration time and then causes power from the power source to be supplied to the one or more loads 820. In this regard, the smart delay device 800 may be configured to drive the one or more loads 820 directly. In an example embodiment, the smart delay device 800 drives the one or more loads 820 using embedding switching. It would be appreciated that in other embodiments, the smart delay device 800 may drive the one or more loads 820 using other techniques.

In the illustrated example of FIG. 8D, the input component 804 is configured for being connected to a control signal source and the output component 806 is configured for being connected to an equipment such that the smart delay device 800 may drive the equipment. The control signal source may be configured for generating an input control signal 828. The input control signal may be indicative of the power supply status of a power source. The input control signal source, for example, may be connected to a power source configured for supplying power to the equipment. The output component may be configured to output a control signal output 830.

The input component 804 of the smart delay device 800 may be configured to receive input control signal 828 supplied by the control signal source. In response to receiving the input control signal 828 (e.g., after a power loss or otherwise interruption of power supplied by the power source), the controller may perform the steps/operations (or portion thereof) described in at least one of FIG. 2A, 2B, 3A, 3B, 3C, 3D, or 4 to determine the power restoration delay time and drive the main contactor 810 in accordance with the power restoration delay time. The control signal on/off, for example, may be analogous with power loss from the electrical distribution system. In various embodiments, the control signal 828 provides both the input signal and also power to the smart delay device 800, and the power restoration delay time is calculated as described in at least one of FIG. 2A, 2B, 3A, 3B, 3C, 3D, or 4.

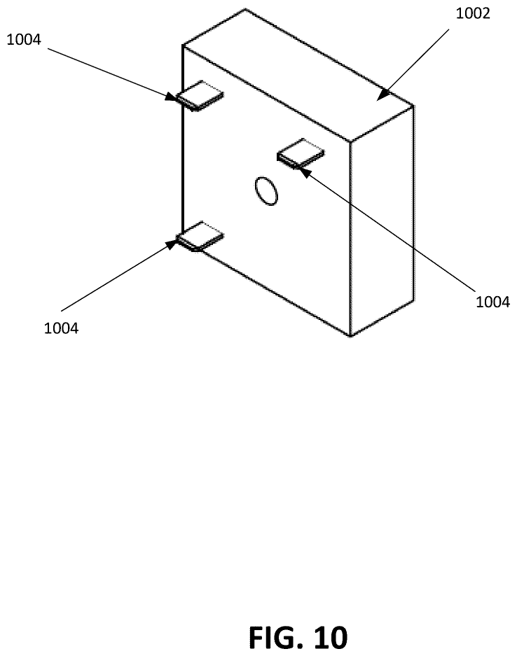

In some embodiments, the smart delay device 800 may be embodied as shown in FIG. 10. In various embodiments, the smart delay device 800 is configured such that it may be seamlessly integrated with or otherwise added to an existing electrical device, product, or system that drives an internal or external output to power equipment, motors, and/or the like. Such existing electrical device, product, or system may or may not have an existing fault control or delay feature. For example, the smart delay device 800 may be integrated or otherwise added to an RV protection device (that may or may not have an existing fault control, or delay feature) without major changes to the RV protection device and provide the functionalities (e.g., power restoration delay feature, and/or the like) described herein. As another example, the smart delay device 800 may be integrated or otherwise added to an operation industrial control system, wherein the power restoration delay feature described herein can reduce the time for equipment to be ready to operate. As yet another example, the smart delay device 800 may be integrated or otherwise added to air condition units or the like, without design changes to the control circuit electronics of the air condition unit. For example, the smart delay device 800 may be inserted into the control line to the contactor.

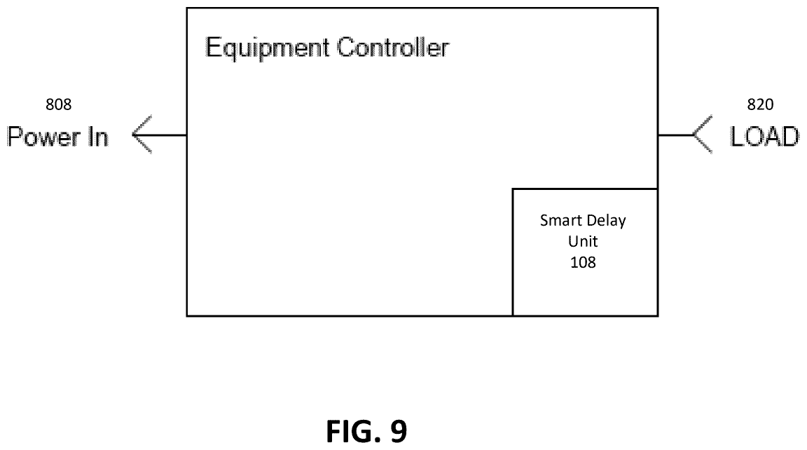

FIG. 9 is a schematic diagram of an example controller 900 with integrated smart delay functionality in accordance with at least one embodiment of the present disclosure. The controller 900 may be a controller of an equipment such as, for example, a refrigeration equipment and/or any equipment that would benefit from power restoration delay following loss of power (e.g., for pressures to stabilize or temperature to cool before restarting). The controller 900 may include a delay time unit (such as delay time unit 108 described above with respect to FIG. 1) integrated within the controller 900. The controller 900 with the delay time unit 108 may be configured to perform the steps/operations described in at least one of FIG. 2A, 2B, 3A, 3B, 3C, 3D, or 4. Specifically, the controller 900 with the delay time unit 108 may be configured to calculate or otherwise determine power restoration delay time for restoring power to the equipment comprising the controller 900 following loss of power or otherwise interruption of power supply from the power source configured to supply power to the equipment.

The controller 900 may be configured to receive input power 808 supplied by the power source. In response to receiving the input power after a power loss or otherwise interruption of power supplied by the power source, the controller 900 (e.g., based on the smart delay time unit 108) may perform the steps/operations (or portion thereof) described in at least one of FIG. 2A, 2B, 3A, 3B, 3C, 3D, or 4 to determine the power restoration delay time and drive one or more loads 820 in accordance with the power restoration delay time.

FIG. 10 shows an example application embodiment of smart delay device, such as smart delay device 800, according to at least some embodiments of the present disclosure. As shown in FIG. 10, the smart delay device 800 may include a housing 1002 configured to house various components of the smart delay device 800. For example, the housing 1002 may house the smart delay circuitry (e.g., described above). The smart delay device 800 may include one or more terminals 1004. In an example embodiment, at least one of the one or more terminals is configured for being connected to a power source and at least one of the one or more terminals is configured for being connected to an electrical distribution system, a load, and/or the like. In some example embodiments, at least one of the one or more terminals is configured for being connected to a control signal source and at least one of the one or more terminals may be configured to output control signal (e.g., the control signal output by the smart delay device 800) or load.

Moreover, many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the application.

1. An apparatus for detecting fault conditions in a power system for delivering power to an electrical distribution system, the apparatus comprising:
one or more powered lines configured to output electricity to the electrical distribution system;
a neutral line configured to provide a grounded neutral to the one or more powered lines;
an interrupter configured to selectively interrupt power supplied by the one or more powered lines; and
a controller in communication with the interrupter, the controller configured for:
detecting when a fault condition is present in the power system;
in response to detecting that the fault condition is present, causing the interrupter to interrupt the power supplied by the one or more powered lines; and
in response to detecting that the fault condition is no longer present: (i) determining a power restoration delay time, and (ii) causing the one or more powered lines to supply power to the electrical distribution system when the power restoration delay time has been elapsed.

2. The apparatus of claim 1, wherein the apparatus further comprises a resistive-capacitive circuit, wherein the controller is in communication with the resistive-capacitive circuit, and wherein the controller is further configured to cause a capacitor of the resistive-capacitive circuit to begin discharging in response to detecting that the fault condition is present.

3. The apparatus of claim 2, wherein the controller is further configured to cause current to flow to the capacitor to recharge the capacitor when the power restoration delay time has been elapsed.

4. The apparatus of claim 2, wherein the controller is further configured to:
determine a capacitor voltage of the capacitor in response to detecting that the fault condition is no longer present; and
determine the power restoration delay time based on the capacitor voltage.

5. The apparatus of claim 4, wherein the power restoration delay time is less than ten seconds when the capacitor voltage is not greater than a minimum threshold voltage.

6. The apparatus of claim 4, wherein the controller is configured to determine the power restoration delay time when the capacitor voltage is greater than a threshold voltage by:
determining a discharge time for the capacitor to discharge to the capacitor voltage; and
determining a difference between a threshold delay time and the discharge time, wherein the power restoration delay time is the difference between the threshold delay time and the discharge time.

7. The apparatus of claim 4, wherein the controller comprises a microprocessor, wherein the microprocessor is configured for measuring the capacitor voltage.

8. The apparatus of claim 4, wherein the controller comprises an analog comparator circuit configured for measuring the capacitor voltage.

9. The apparatus of claim 4, wherein the controller comprises an analog to digital converter configured for measuring the capacitor voltage.

10. The apparatus of claim 1, wherein the controller is configured to detect that the fault condition is no longer present when power from a power source configured to supply power to the one or more powered lines satisfies one or more power condition criteria.

11. The apparatus of claim 10, wherein the interrupter comprises:
a driver interface in communication with the controller; and
a contactor connected to the driver interface and configured to interrupt the power from the power source when the fault condition is detected.

12. The apparatus of claim 1, wherein the fault condition comprises one or more of an open neutral condition, a high voltage condition, a low voltage condition, a mis-wired power pedestal condition, an open ground condition, a reverse polarity condition, a high neutral current surge condition, an overheating plug condition, or a loss of power source condition.

13. An apparatus for detecting fault conditions in a power system for delivering power to an electrical distribution system, the apparatus comprising:
one or more powered lines configured to output electricity to the electrical distribution system;
a neutral line configured to provide a grounded neutral to the one or more powered lines;
an interrupter configured to selectively interrupt power supplied by the one or more powered lines;
a timer circuit comprising a counter; and
a controller in communication with the interrupter and the timer circuit, the controller configured for:
detecting when a fault condition is present in the power system;
in response to detecting that the fault condition is present, causing the interrupter to interrupt the power supplied by the one or more powered lines and activating the counter; and
in response to detecting that the fault condition is no longer present: (i) determining a remaining count via the counter; (ii) determining a power restoration delay time based on the remaining count and, (iii) causing the one or more powered lines to supply power to the electrical distribution system when the power restoration delay time has been elapsed.

14. The apparatus of claim 13, wherein activating the counter comprises causing the counter to count down, and wherein the power restoration delay time is less than ten seconds when the remaining count is not greater than a minimum remaining count.

15. The apparatus of claim 13, wherein the controller is configured to determine the power restoration delay time when the remaining count is greater than a minimum remaining count by determining a difference between a threshold delay time and the remaining count, wherein the power restoration delay time is the difference between the threshold delay time and the remaining count.

16. The apparatus of claim 13, wherein the controller is configured to detect that the fault condition is no longer present when power from a power source configured to supply power to the one or more powered lines satisfies one or more power condition criteria.

17. An apparatus for detecting fault conditions in a power system for delivering power to an electrical distribution system, the apparatus comprising:
one or more powered lines configured to output electricity to the electrical distribution system;
a neutral line configured to provide a grounded neutral to the one or more powered lines;
an interrupter configured to selectively interrupt power supplied by the one or more powered lines;
a clock; and
a controller in communication with the interrupter and the clock, the controller configured for:
detecting when a fault condition is present in the power system;
in response to detecting that the fault condition is present, causing the interrupter to interrupt the power supplied by the one or more powered lines and determining, via the clock, a first timestamp; and
in response to detecting that the fault condition is no longer present: (i) determining, via the clock, a second timestamp; (ii) determining a power restoration delay time based on the first timestamp and the second timestamp, and (iii) causing the one or more powered lines to supply power to the electrical distribution system when the power restoration delay time has been elapsed.

18. The apparatus of claim 17, wherein the controller is configured to determine the power restoration delay time by determining a difference between the second timestamp and the first timestamp and comparing the difference between the second timestamp and the first timestamp to a threshold delay time.

19. The apparatus of claim 18, wherein the power restoration delay time is less than ten seconds when the difference between the second timestamp and the first timestamp is greater than the threshold delay time.

20. The apparatus of claim 18, wherein the power restoration delay time is the difference between the second timestamp and the first timestamp when the difference between the second timestamp and the first timestamp is less than the threshold delay time.
